(19) United States
(12) Patent Application Publication
(10) Pub. No.: US 2024/0313145 A1
(43) Pub. Date: Sep. 19, 2024

(54) LIGHT RECEIVING ELEMENT

(71) Applicant: AIO CORE CO., LTD., Tokyo (JP)

(72) Inventors: Shinichi Watanuki, Tokyo (JP); Kazuhiro Shiba, Tokyo (JP)

(21) Appl. No.: 18/605,325

(22) Filed: Mar. 14, 2024

(30) Foreign Application Priority Data
Mar. 15, 2023 (JP) 2023-040426

(51) Int. Cl. H01L 31/109; H01L 31/0352

(52) U.S. Cl. CPC H01L 31/109; H01L 31/03529

(57) ABSTRACT

A light receiving element, in which dependency of a light sensitivity characteristic on a light wavelength and on a film thickness of a light absorbing layer is lowered, is provided. The light receiving element comprises a first semiconductor layer which is formed on a substrate or constitutes a part of the substrate, a light absorbing layer formed on the first semiconductor layer, and a second semiconductor layer formed on the light absorbing layer, and the first semiconductor layer comprises plural regions having film thicknesses that are different from one another.

### TECHNICAL FIELD

The present invention relates to a light receiving element.

### BACKGROUND ART

Semiconductor light receiving elements for optical communication, such as a light receiving element constructed in such a manner that light enters a light absorbing layer from a side thereof via an optical waveguide constructed in a position below the light absorbing layer (for example, refer to Patent Literature 1), and a surface-illuminated-type light receiving element constructed in such a manner that light enters a light absorbing layer from a position above the light absorbing layer, i.e., in a direction perpendicular to a top surface of the light absorbing layer (for example, refer to Patent Literature 2), have been developed. In the former-type light receiving element, it is difficult to improve the efficiency of coupling of light to the waveguide, and, on the other hand, in the latter-type light receiving element, there is an advantage that it can receive light by the light absorbing layer highly efficiently.

### CITATION LIST

### Patent Literature

PTL 1: Japanese Patent Application Public Disclosure No. 2012-256869
PTL2: Japanese Patent Application Public Disclosure No. 2022-161169

### SUMMARY OF INVENTION

### Technical Problem

On the other hand, study and development with respect to a silicon photonics device, in which a semiconductor light receiving element and other optical/electrical elements are integrated, has been made. In such a silicon photonics device, it is difficult to manufacture a light absorbing layer having sufficient thickness; accordingly, lowering of the degree of light sensitivity is prevented by increasing effective thickness of the light absorbing layer by using multiple reflection of light in a multilayer film including the light absorbing layer. However, due to multiple reflection of light in the multilayer film, a problem such that the characteristic of the light sensitivity becomes dependent on a light wavelength or a film thickness of the light absorbing layer arises.

The present invention has been achieved in view of the above matters; and an object of the present invention is to provide a light receiving element in which dependency of a light sensitivity characteristic on a light wavelength and on a film thickness of a light absorbing layer is lowered.

### Solution to Problem

For solving the above-explained problems, a light receiving element is provided according to a mode of the present invention, wherein the provided light receiving element is that comprising: a first semiconductor layer which is formed on a substrate or constitutes a part of the substrate; a light absorbing layer formed on the first semiconductor layer; and a second semiconductor layer formed on the light absorbing layer; wherein the first semiconductor layer comprises plural regions having film thicknesses that are different from one another.

Further, according to a different mode of the present invention, a light receiving element, which has the construction in the above-explained mode and in which the number of the plural regions in the first semiconductor layer is equal to or greater than 3, is provided.

Further, according to a different mode of the present invention, a light receiving element, which has the construction in the above-explained mode and in which the first semiconductor layer is formed on a first dielectric layer, is provided.

Further, according to a different mode of the present invention, a light receiving element, which has the construction in the above-explained mode and further comprises a second dielectric layer on the second semiconductor layer, is provided.

Further, according to a different mode of the present invention, a light receiving element, which has the construction in the above-explained mode and in which the first dielectric layer is a buried oxide film in an SOI substrate, and the first semiconductor layer is an Si thin film on the buried oxide film in the SOI substrate, is provided.

Further, according to a different mode of the present invention, a light receiving element, which has the construction in the above-explained mode and in which the light absorbing layer is a layer comprising Ge, is provided.

### Advantageous Effects of Invention

According to the present invention, a light receiving element, in which dependency of a light sensitivity characteristic on a light wavelength and on a film thickness of the light absorbing layer is lowered, can be realized.

### BRIEF DESCRIPTION OF DRAWINGS

FIG. 1 is a figure showing a schematic cross-sectional construction of a light receiving element according to an embodiment.

FIG. 2A is an example of a graph of quantum efficiency of the light receiving element having the construction shown in FIG. 1.

FIG. 2B is an example of a graph of quantum efficiency of the light receiving element having the construction shown in FIG. 1.

FIG. 2C is an example of a graph of quantum efficiency of the light receiving element having the construction shown in FIG. 1.

FIG. 3 is a figure showing a schematic cross-sectional construction of a light receiving element according to an embodiment of the present invention.

FIG. 4 is a figure showing a schematic cross-sectional construction of a light receiving element according to an embodiment of the present invention.

FIG. 5 is an example of a graph of quantum efficiency of the light receiving element shown in FIG. 3.

FIG. 6 is an example of a graph of quantum efficiency of the light receiving element shown in FIG. 4.

FIG. 7 is a figure showing examples of plane structures of the p-type semiconductor layer in the light receiving element shown in FIG. 4.

### DESCRIPTION OF EMBODIMENTS

In the following description, embodiments of the present invention will be explained in detail, with reference to the figures.

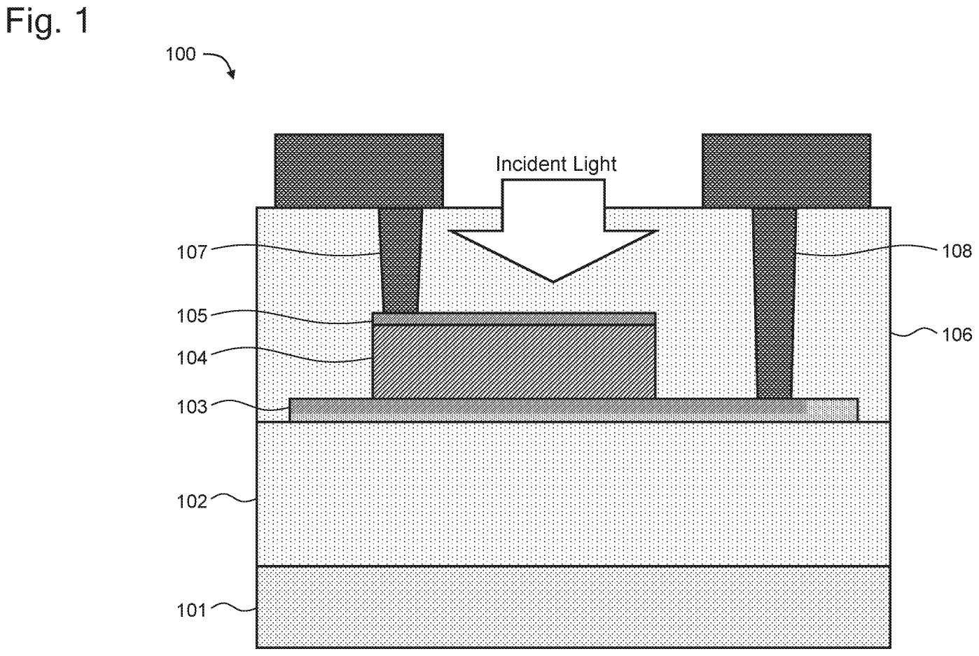

FIG. 1 is a figure showing a schematic cross-sectional construction of a light receiving element 100 according to an embodiment. The light receiving element 100 comprises a p-type semiconductor layer 103 formed on a buried oxide film (BOX layer) 102, an i-type semiconductor layer 104 formed on the p-type semiconductor layer 103, and an n-type semiconductor layer 105 formed on the i-type semiconductor layer 104; and has a pin structure in which the i-type semiconductor layer 104 is held in a position between the p-type semiconductor layer 103 and the n-type semiconductor layer 105. The light receiving element 100 is manufactured by using an SOI (Silicon On Insulator) substrate which comprises a bulk silicon (Si) layer 101, the box layer 102, and an SOI layer on the BOX layer 102.

The p-type semiconductor layer 103 is a layer comprising silicon in which a p-type impurity has been doped. For example, boron (B) may be used as the p-type impurity. The p-type semiconductor layer 103 is formed by performing doping of the SOI layer on the BOX layer 102 by using the p-type impurity.

The i-type semiconductor layer 104 is a layer comprising germanium (Ge) or silicon-germanium (SiₓGe₁₋ₓ) which is not doped by any impurity. The i-type semiconductor layer 104 is formed by epitaxially growing a crystal layer of germanium or silicon-germanium on the p-type semiconductor layer 103.

The n-type semiconductor layer 105 is a semiconductor layer in which an n-type impurity has been doped, and comprises silicon or silicon-germanium, for example. Phosphorus (P), arsenic (As), or the like may be used as the n-type impurity, for example. The n-type semiconductor layer 105 is formed by epitaxially growing a crystal layer of silicon or the like on the i-type semiconductor layer 104 to cover a top surface thereof, and further performing doping of the semiconductor layer by using the n-type impurity. It should be reminded that, although the side of the i-type semiconductor layer 104 is drawn in FIG. 1 in such a manner that it stands vertically, the side in reality comprises an inclined surface which is dependent on crystal orientation of atoms which are components of the i-type semiconductor layer 104, and the silicon crystal layer is also epitaxially grown on the inclined surface. In this regard, in FIG. 1, drawing of the silicon crystal layer covering the side of the i-type semiconductor layer 104 is omitted.

The surface of the light receiving element 100 is covered by an insulating film (for example, an SiO₂ film) 106. In a part, which is positioned above the n-type semiconductor layer 105, of the insulating layer 106, an opening which reaches the surface of the n-type semiconductor layer 105 is formed, and a first metal electrode 107 is formed in the opening. Further, in a part, which is distant from the n-type semiconductor layer 105 and the i-type semiconductor layer 104 and positioned above the p-type semiconductor layer 103, of the insulating layer 106, an opening which reaches the surface of the p-type semiconductor layer 103 is formed, and a second metal electrode 108 is formed in the opening.

The first metal electrode 107 is an electrode for applying a voltage to the light receiving element 100, and, usually, a voltage in a range of approximately 2-10 volts is applied to the electrode. The second metal electrode 108 is an electrode for taking out an electric signal, and is connected to a transimpedance amplifier (this is not shown in the figure) for converting and amplifying small current, that is generated as a result of photoelectric conversion, to a voltage signal.

The light receiving element 100 is constructed in such a manner that the light coming from a position above the n-type semiconductor layer 105 enters the i-type semiconductor layer 104 via the insulating film 106 and the n-type semiconductor layer 105. When the light receiving element 100 is activated, a reverse bias voltage is applied between the p-type semiconductor layer 103 and n-type semiconductor layer 105 via the first metal electrode 107 and the second metal electrode 108, and, as a result, a depletion layer is formed in the i-type semiconductor layer 104. The incident light entering the i-type semiconductor layer 104 is absorbed by the i-type semiconductor layer 104, and, as a result, photocarriers (electrons and holes) are generated in the i-type semiconductor layer 104. The electrons and the holes generated in the i-type semiconductor layer 104 are affected by an electric field in the depletion layer, and, as a result, the electrons and the holes move from the i-type semiconductor layer 104 to the n-type semiconductor layer 105 and p-type semiconductor layer 103, respectively. Consequently, photoelectric current flows through the light receiving element 100.

In this regard, quantum efficiency (or light sensitivity) of the light receiving element 100 becomes higher as the distance that the incident light, that has entered the i-type semiconductor layer 104 which is the light absorbing layer, propagates in the i-type semiconductor layer 104 becomes longer, since the quantity of generated photocarriers increases as the distance increases. In the light receiving element 100, the light propagates through the i-type semiconductor layer 104 in such a manner that many number of times of movement of the light in a reciprocating manner in upward and downward directions (the upward/downward directions in FIG. 1) in the multilayer film including the i-type semiconductor layer 104 occur due to multiple reflection of the light therein; thus, even if the film thickness of the i-type semiconductor layer 104 is thin, the effective length of the propagation distance of the light in the i-type semiconductor layer 104 becomes long, and high quantum efficiency can be achieved.

On the other hand, due to the occurrence of multiple reflection, there is dependency of quantum efficiency of the light receiving element 100 on the wavelength of light and on the film thickness of each of the layers forming the multilayer film. In the case that the light receiving element 100 is incorporated in an optical communication system, the wavelength of an optical signal, that is to be transmitted, changes according to temperature of an environment wherein a transmitter is arranged, since the emission wavelength of a semiconductor laser used in the transmitter in general is dependent on temperature. Thus, it is desired to lower the degree of wavelength-dependency of quantum efficiency of the light receiving element 100. Further, since dependency of quantum efficiency of the light receiving element 100 on the film thickness of the i-type semiconductor layer 104, which works as the light absorbing layer, is remarkable, it is desired to lower the degree of dependency.

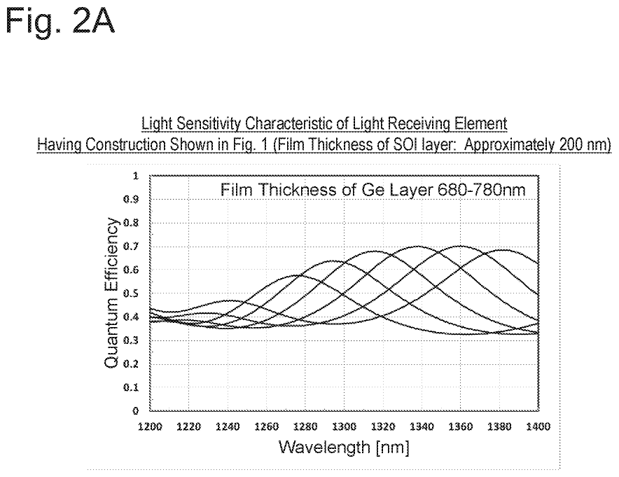

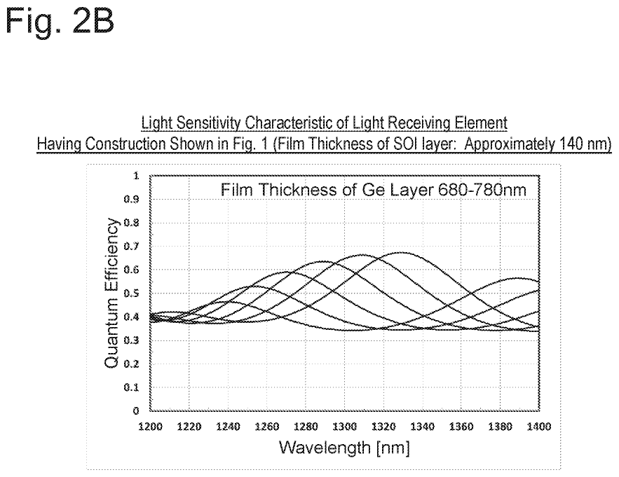

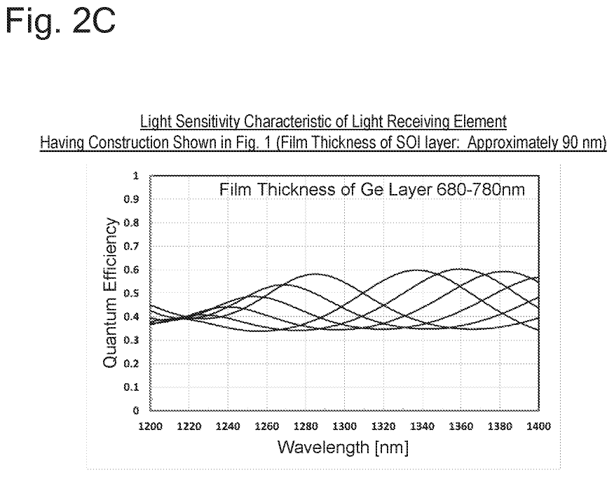

Each of FIGS. 2A, 2B, and 2C is an example of a graph of quantum efficiency of the light receiving element 100 having the construction shown in FIG. 1. The above figures show wavelength-dependency of quantum efficiency in the light receiving elements 100 including the p-type semiconductor layers 103 (SOI layers) having film thicknesses of approximately 200 nm, approximately 140 nm, and approximately 90 nm, respectively; and, in each of the figures, the horizontal axis represents the wavelength of light and the vertical axis represents the quantum efficiency. Further, in each of the figures, plural graphs relating to i-type semiconductor layers 104, which comprise germanium and have different film thicknesses (680 nm-780 nm), respectively, are plotted and shown. Based on the above graphs, it can be understood with respect to the light receiving element 100 having the construction shown in FIG. 1 that dependency of quantum efficiency on the wavelength of the light and on the film thickness of the i-type semiconductor layer 104 is high. In this regard, the wavelength-dependency of quantum efficiency such as that explained above exists in relation to the characteristic that the reflectance in multilayer film is wavelength-dependent, so that the wavelength-dependency of the reflectance, thus, the wavelength-dependency of the quantum efficiency becomes higher as a difference between refractive indexes in the multilayer film becomes larger. Since the light receiving element 100 comprises a semiconductor layer and a dielectric layer (102, 106) and the difference between refractive indexes of them is large, the wavelength-dependency of the quantum efficiency in the light receiving element 100 is relatively high.

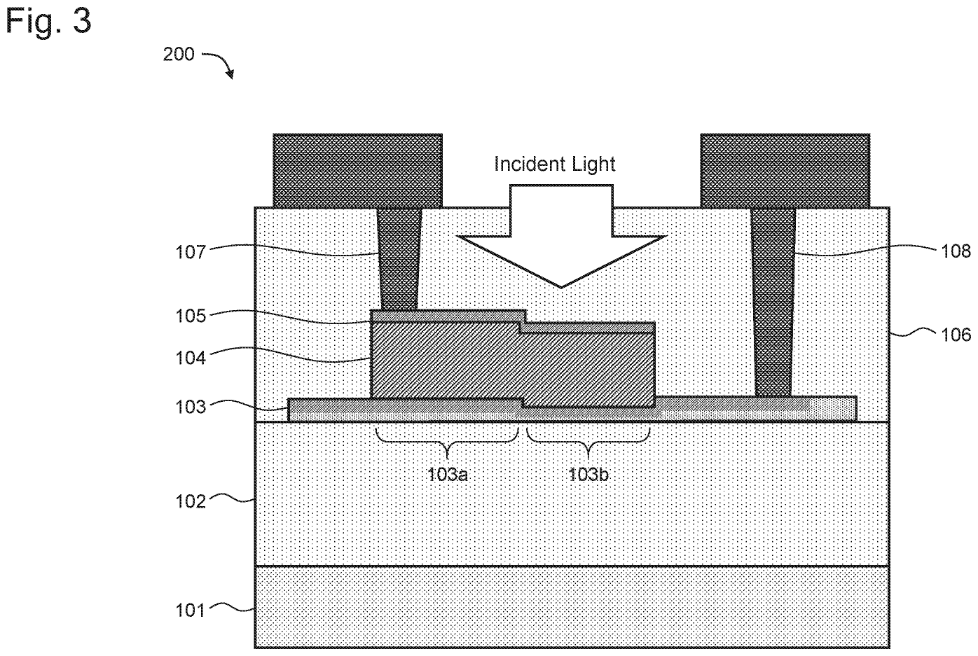

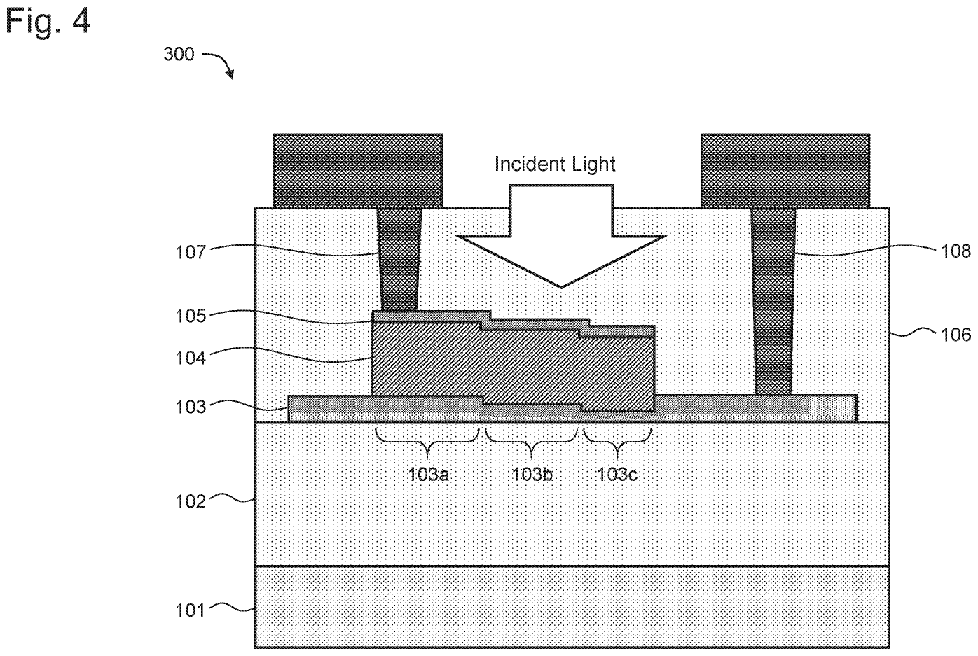

FIG. 3 and FIG. 4 are figures showing schematic cross-sectional constructions of light receiving elements 200 and 300 according to embodiments of the present invention that can solve the above-explained problems. In each of FIGS. 3 and 4, reference symbols have been assigned to elements included in the light receiving element 100 shown in FIG. 1 are assigned to elements which are similar to those included in the light receiving element 100, respectively, and overlapping explanation of these similar elements will be omitted herein.

Each of the light receiving elements 200 and 300 comprises a p-type semiconductor layer 103 comprising plural regions. Specifically, the p-type semiconductor layer 103 in the light receiving element 200 in FIG. 3 comprises a first region 103a and a second region 103b, and the p-type semiconductor layer 103 in the light receiving element 300 in FIG. 4 comprises a first region 103a, a second region 103b, and a third region 130c. The number of regions in the p-type semiconductor layer 103 is not limited to 3 or 4, and it may be 4 or more than 4. The regions 103a, 103b, and 103c in the p-type semiconductor layer 103 are constructed to have different film thicknesses, respectively. For example, the thickness of the first region 103a may be approximately 200 nm that corresponds to the value relating to above-explained FIG. 2A, the thickness of the second region 103b may be approximately 140 nm that corresponds to the value relating to above-explained FIG. 2B, and the thickness of the third region 103c may be approximately 90 nm that corresponds to the value relating to above-explained FIG. 2C. It should be reminded that the above values are mere examples, and it is needless to state that the values of thickness of the respective regions may be different from the above values.

In each of the light receiving elements 200 and 300, an i-type semiconductor layer 104 similar to that in the light receiving element 100 in FIG. 1 is formed on the p-type semiconductor layer 103 comprising plural regions, and, further, an n-type semiconductor layer 105 similar to that in the light receiving element 100 in FIG. 1 is formed on the i-type semiconductor layer 104. The thicknesses of the parts, that are in positions above the respective regions of the p-type semiconductor layer 103, of the i-type semiconductor layer 104 are equal to one another, and the thicknesses of the parts, that are in positions above the respective regions of the p-type semiconductor layer 103, of the n-type semiconductor layer 105 are equal to one another. Thus, each of the light receiving elements 200 and 300 is different from the light receiving element 100 in FIG. 1, only in the point that the film thicknesses of the regions in the p-type semiconductor layer 103 are different from one another in each of the light receiving elements 200 and 300.

Regarding each of FIGS. 3 and 4, it should be reminded that, although each of the interface between the i-type semiconductor layer 104 and the n-type semiconductor layer 105 and the interface between the n-type semiconductor layer 105 and the insulating film 106 is drawn in the figure in such a manner that it has a step-shape part(s) in a position(s) above a border(s) between consecutive regions in the p-type semiconductor layer 103, the surfaces of the i-type semiconductor layer 104 and the n-type semiconductor layer 105 are constructed to be smooth (or the part(s) that have been drawn as that having the step-shape(s) is(are) formed to have an inclined shape(s)) in actuality in the film-forming process for the i-type semiconductor layer 104 and the film-forming process for the n-type semiconductor layer 105.

Each of the light receiving elements 200 and 300 has different light sensitivity characteristics (the above-explained wavelength dependency and film-thickness dependency of the quantum efficiency) in the regions having different film thicknesses, respectively. For example, in the light receiving element 300 in FIG. 4, if it is supposed that the film thicknesses of the first region 103a, the second region 103b, and the third region 130c of the p-type semiconductor layer 103 are approximately 200 nm, approximately 140 nm, and approximately 90 nm, respectively, a partial light-receiving-element 300a comprising respective parts of semiconductor layers corresponding to the first region 103a in the whole light receiving element 300 has the light sensitivity characteristic shown in FIG. 2A, a partial light-receiving-element 300b corresponding to the second region 103b has the light sensitivity characteristic shown in FIG. 2B, and a partial light-receiving-element 300c corresponding to the third region 103c has the light sensitivity characteristic shown in FIG. 2C. Thus, the light sensitivity characteristic of the whole light receiving element 300 is determined by averaging the light sensitivity characteristics shown in FIGS. 2A, 2B, and 2C.

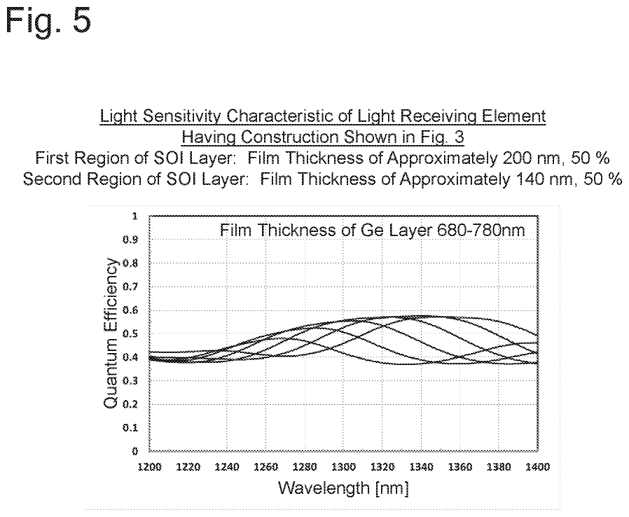

FIG. 5 is an example of a graph of quantum efficiency of the light receiving element 200 shown in FIG. 3. FIG. 5 shows wavelength dependency of the quantum efficiency in the light receiving element 200, in the case that the p-type semiconductor layer 103 comprises the first region 103a having thickness of approximately 200 nm and the second region 103b having thickness of approximately 140 nm, and the ratios of the first region 103a and the second region 103b in the whole p-type semiconductor layer 103 (for example, ratios of areas in plan view) are 50% and 50%, respectively. As will be understood from the graph, in the case that the light receiving element 200 comprises the p-type semiconductor layer 103 comprising two regions having different film thicknesses, the wavelength dependency of the quantum efficiency becomes gentle, and the dependency on the film thickness of the i-type semiconductor layer 104 is also softened, compared with the light receiving element 100 having the construction shown in FIG. 1.

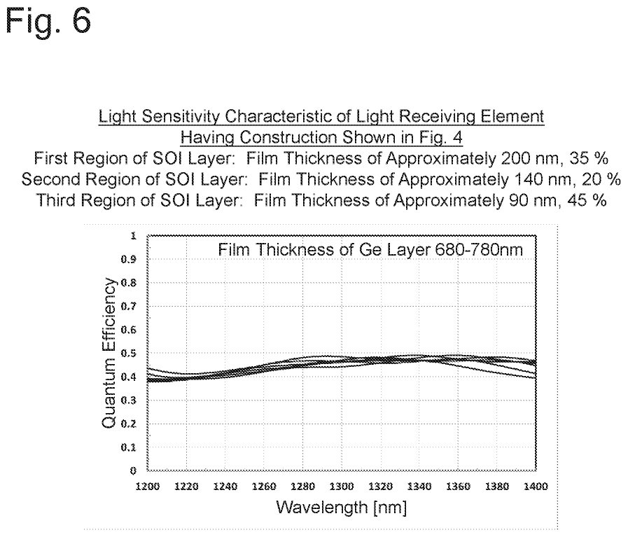

FIG. 6 is an example of a graph of quantum efficiency of the light receiving element 300 shown in FIG. 4. FIG. 5 shows wavelength dependency of the quantum efficiency in the light receiving element 300, in the case that the p-type semiconductor layer 103 comprises the first region 103a having thickness of approximately 200 nm, the second region 103b having thickness of approximately 140 nm, and the third region 103c having thickness of approximately 90 nm, and the ratios of the first region 103a, the second region 103b, and the third region 103c in the whole p-type semiconductor layer 103 (for example, ratios of areas in plan view) are 35%, 20%, and 45%, respectively. In the case that the light receiving element 300 comprises the p-type semiconductor layer 103 comprising three regions having different film thicknesses as explained above, the quantum efficiency becomes nearly flat through all wavelength regions (the region of wavelengths from 1200 nm to 1400 nm shown in FIG. 6), and the dependency on the film thickness of the i-type semiconductor layer 104 is also largely eliminated.

It should be reminded that the above values relating to the light receiving element 200 relating to the graph in FIG. 5 and the light receiving element 300 relating to the graph in FIG. 6 (that is, the value relating to film thicknesses and the value relating to rations of respective regions) are mere example, and the values may be optimized appropriately for realizing a desired light sensitivity characteristic (for example, flat wavelength dependency of quantum efficiency) of the light receiving element.

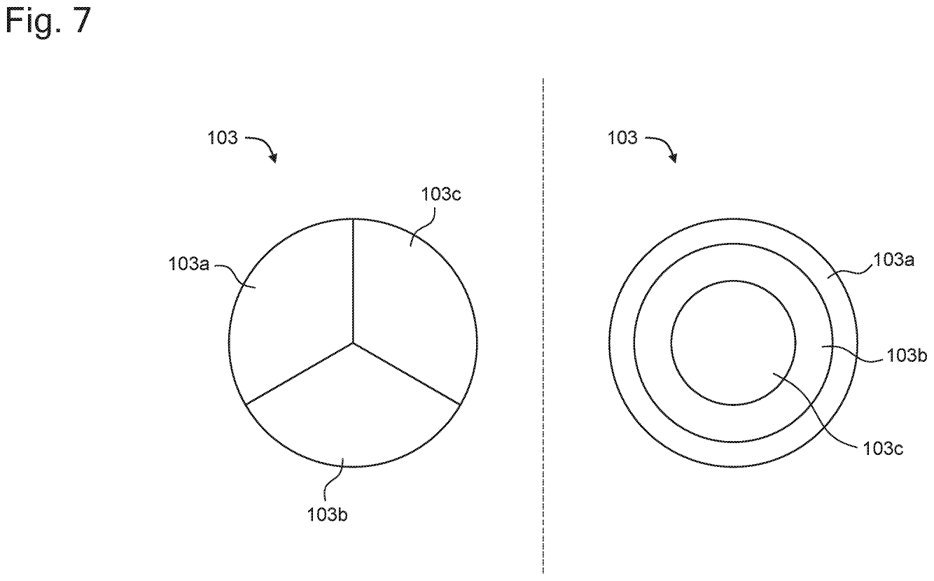

FIG. 7 is a figure showing examples of plane structures of the p-type semiconductor layer 103 in the light receiving element 300 shown in FIG. 4. The first region 103a, the second region 103b, and the third region 130c in the p-type semiconductor layer 103 may be constructed to have fan shapes such as those shown in the figure on the left side of FIG. 7 or may be constructed to have concentric circular shapes such as those shown in the figure on the right side of FIG. 7. As explained above, the number of regions in the p-type semiconductor layer 103 can be determined appropriately. The shapes of the respective regions in the p-type semiconductor layer 103 may be those other than the fan shapes and the concentric circular shapes.

Although embodiments of the present invention have been explained in the above description, the present invention is not limited to any of them; and the embodiments can be modified in various ways without departing from the scope of the gist of the present invention.

### REFERENCE SIGNS LIST

100 Light receiving element
101 Bulk silicon layer
102 Buried oxide film (BOX layer)
103 p-type semiconductor layer
103a First region
103b Second region
103c Third region
104 i-type semiconductor layer
105 n-type semiconductor layer
106 Insulating film
107 First metal electrode
108 Second metal electrode
200 Light receiving element
300 Light receiving element

What is claimed is:

1. A light receiving element comprising:
a first semiconductor layer, the first semiconductor layer formed on a substrate or constituting a part of the substrate;
a light absorbing layer formed on the first semiconductor layer; and
a second semiconductor layer formed on the light absorbing layer; wherein
the first semiconductor layer comprises plural regions having film thicknesses that are different from one another.

2. The light receiving element as recited in claim 1, wherein the number of the plural regions in the first semiconductor layer is equal to or greater than 3.

3. The light receiving element as recited in claim 1, wherein the first semiconductor layer is formed on a first dielectric layer.

4. The light receiving element as recited in claim 3, further comprising a second dielectric layer on the second semiconductor layer.

5. The light receiving element as recited in claim 3, wherein
the first dielectric layer is a buried oxide film in an SOI substrate, and
the first semiconductor layer is an Si thin film on the buried oxide film in the SOI substrate.

6. The light receiving element as recited in claim 1, wherein the light absorbing layer is a layer comprising Ge.
